(19) United States
(12) Patent Application Publication
(10) Pub. No.: US 2015/0245546 A1
(43) Pub. Date: Aug. 27, 2015

(54) ELECTROSTATIC DISCHARGE PROTECTION CIRCUIT

(71) Applicant: Nuvoton Technology Corporation, Hsinchu Science Park (TW)

(72) Inventor: Da-Hsien LIN, New Taipei City (TW)

(21) Appl. No.: 14/479,976

(22) Filed: Sep. 8, 2014

(30) Foreign Application Priority Data
Feb. 24, 2014 (TW) 103106013

(51) Int. Cl. H05K 9/00; H01G 17/00; H01L 27/02

(52) U.S. Cl. CPC H05K 9/0067; H01L 27/0266; H01G 17/00

(57) ABSTRACT

A semiconductor device is provided. The semiconductor device includes: a high-pass filter circuit, configured to provide a first voltage; an electrostatic discharge (ESD) protection device; and a trigger circuit, coupled to the high-pass filter circuit and the ESD protection device, wherein when an ESD event caused by positive electric charges occurs on a first rail, the trigger circuit provides a second voltage, which is lower than the first voltage, to the ESD protection device, so that electric charges of the ESD event are directed to a second rail through the ESD protection device.

### CROSS REFERENCE TO RELATED APPLICATIONS

This application claims priority of Taiwan Patent Application No. 103106013, filed on Feb. 24, 2014, the entirety of which is incorporated by reference herein.

### BACKGROUND OF THE INVENTION

1. Field of the Invention

The embodiments of the present invention relates to semiconductor technology, and in particular to an electrostatic discharge protection circuit deployed in a semiconductor device.

2. Description of the Related Art

Electrostatic discharge (ESD) is the sudden and momentary electric current that flows when an excess of electric charge, stored on an electrically insulated object, finds a path to an object at a different electrical potential such as ground. When a static charge moves in an integrated circuit (IC), it becomes a current that damages or destroys gate oxide, metallization and junctions. ESD can occur when a charged body touches an IC, a charged IC touches a grounded surface, or a charged machine touches an IC.

ESD is a common phenomenon that occurs during the handling of semiconductor devices. Electrostatic charges may accumulate and cause potentially destructive effects on a semiconductor IC device. ESD stress can occur during the testing phase of IC fabrication, during installation of the IC onto a circuit board, as well as during use of equipment in which the IC has been installed. ESD damage to a single IC in an electronic device can partially or sometimes completely stop its operation.

As technology advances, ESD durability has become an increasing concern for IC manufacture. As semiconductor processing technology has advanced into deep submicron regimes, the resulting scaled-down semiconductor devices that include shallower junction depths and thinner gate oxide layers are less tolerant to ESD stress. Therefore, ESD protection circuits must be implemented at the I/O pads of the IC to prevent damage from ESD stress.

### BRIEF SUMMARY OF THE INVENTION

A detailed description is given in the following embodiments with reference to the accompanying drawings.

In an exemplary embodiment, an electrostatic discharge (ESD) protection circuit is provided. The ESD protection circuit includes: a filter circuit including: a capacitor, wherein a first terminal of the capacitor is coupled to a first rail having a first voltage, and a second terminal of the capacitor is coupled to a first node; and a first resistor, wherein a first terminal of the first resistor is coupled to the first node, and a second terminal of the first resistor is coupled to a second rail having a second voltage, wherein the first voltage is higher than the second voltage; an ESD protection device, including: a first NMOS having a gate, a drain, and a source, wherein the drain is coupled to the first rail, and the source is coupled to the second rail, and the gate receives a third voltage to activate the first NMOS; and a trigger circuit, coupled between the filter circuit and the ESD protection device.

In another exemplary embodiment, a semiconductor device is provided. The semiconductor device includes: a high-pass filter circuit, configured to provide a first voltage; an electrostatic discharge (ESD) protection device; and a trigger circuit, coupled to the high-pass filter circuit and the ESD protection device, wherein when an ESD event caused by positive electric charges occurs on a first rail, the trigger circuit provides a second voltage, which is lower than the first voltage, to the ESD protection device, so that electric charges of the ESD event are directed to a second rail through the ESD protection device.

In yet another exemplary embodiment, an electrostatic discharge (ESD) protection circuit is provided. The ESD protection circuit includes: a filter circuit, an ESD protection device, and a buffer circuit. The filter circuit includes: a capacitor and a resistor. A first terminal of the capacitor is coupled to a first rail having a first voltage, and a second terminal of the capacitor is coupled to a first node. A first terminal of the first resistor is coupled to the first node, and a second terminal of the first resistor is coupled to a second rail having a second voltage, wherein the first voltage is higher than the second voltage. The ESD protection device includes: a first NMOS having a gate, a drain, and a source, wherein the drain is coupled to the first rail, and the source is coupled to the second rail, and the gate receives a third voltage to activate the first NMOS. The buffer circuit is coupled between the filter circuit and the ESD protection device, and the buffer circuit is implemented by a first resistor or a diode.

### BRIEF DESCRIPTION OF THE DRAWINGS

The present invention can be more fully understood by reading the subsequent detailed description and examples with references made to the accompanying drawings, wherein:

FIG. 1 is a simplified block diagram of an electrostatic discharge protection system;

FIG. 2A is a schematic diagram of an ESD protection circuit 210 implemented by GGNMOS;

FIG. 2B is a schematic diagram of an ESD protection circuit 220 implemented by ground-gated NMOS with resistor (GRNMOS);

FIG. 2C is a schematic diagram of an ESD protection circuit 230 implemented by an RC-inverter NMOS;

FIG. 3 is a schematic block diagram of the ESD protection circuit 300 in accordance with an embodiment of the invention;

FIG. 4A is a schematic diagram of the ESD protection circuit 300 in accordance with an embodiment of the invention;

FIG. 4B is a schematic diagram of the ESD protection circuit 300 in accordance with another embodiment of the invention;

FIG. 5 is a diagram illustrating the filter gain of the filter circuit 310 in accordance with an embodiment of the invention;

FIGS. 6A-6B are diagrams illustrating the frequency response of the ESD protection circuit 300 in accordance with an embodiment of the invention; and

FIGS. 7A-7B are diagrams illustrating the frequency response of the ESD protection circuit 230 shown in FIG. 2C.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

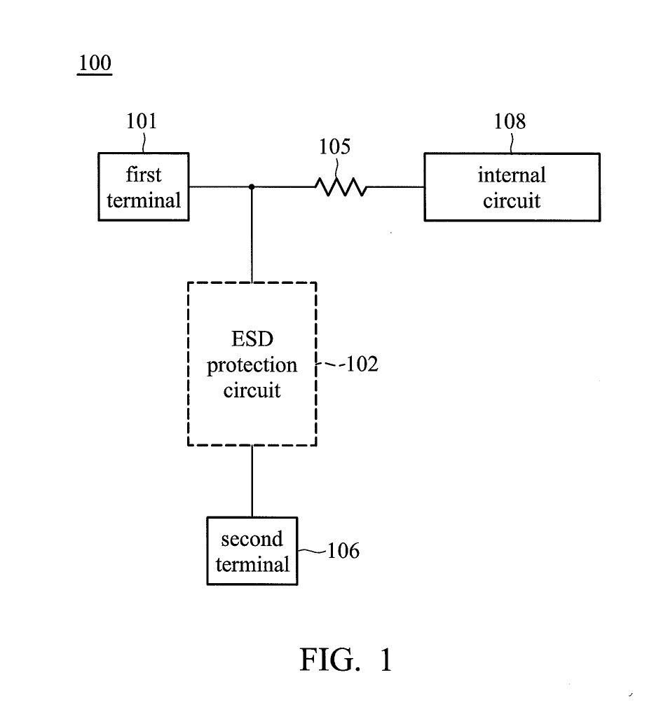

FIG. 1 is a simplified block diagram of an electrostatic discharge protection system. The electrostatic discharge (ESD) protection system 100 may primarily include a first terminal 101, an ESD protection circuit 102, a second terminal 106, and an internal circuit 108. The first terminal 101 may be coupled to an input/output pad, or the power supply terminal having a higher voltage level (e.g. VDD). The second terminal 106 may be coupled to a power supply terminal having a lower voltage level (e.g. GND or VSS). When an ESD event (e.g. ESD pulse) occurs at the first terminal 101, the ESD protection circuit 102 coupled between the first terminal 101 and the second terminal 106 can be used to protect the internal circuit 108. The ESD protection circuit 102 may be the primary ESD protection apparatus, which allows the large current caused by the ESD event to be discharged to the second terminal 106 by limiting the voltage level. Accordingly, the ESD protection circuit 102 may prevent from the ESD pulse occurring at the first terminal 101.

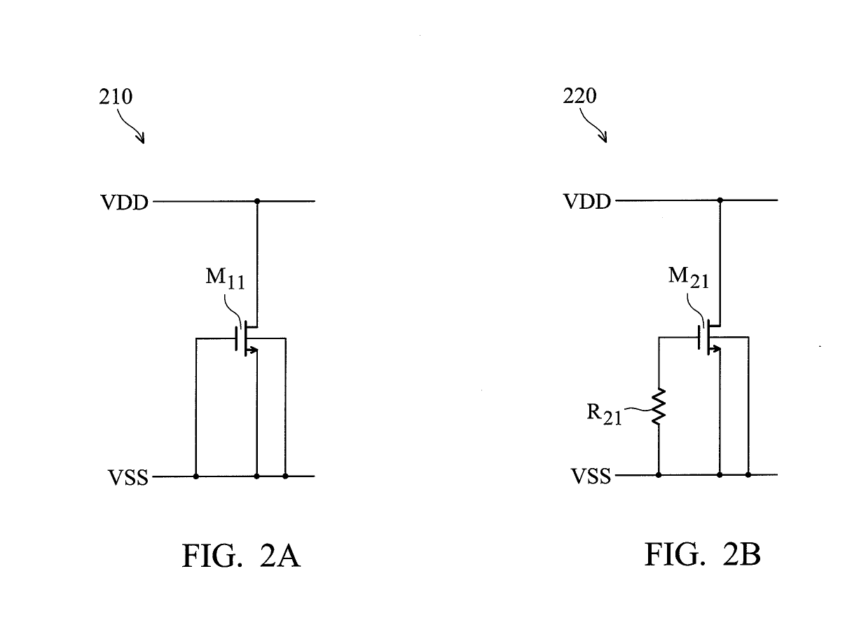

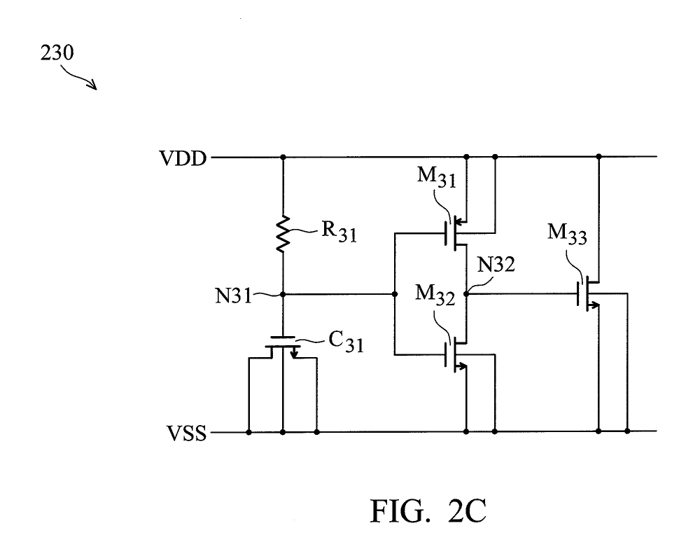

For example, the ESD protection circuit 102 may include a diode chain having one or more diodes connected in series, a grounded-gate NMOS (GGNMOS, as shown in FIG. 2A) having a gate terminal, source terminal and a drain terminal, or circuits shown in FIG. 2B and FIG. 2C. The ESD protection circuit 102 located between the first terminal 101 and the second terminal 106 may be coupled to or connected in parallel to the components to be protected or the internal circuit 108. The ESD protection circuit 102 is designed to be triggered before the ESD current causes damage to the internal circuit 108. In other embodiments, a resistor 105 can be used as an extra protection component to limit the current flowing to the internal circuit 108.

FIG. 2A is a schematic diagram of an ESD protection circuit 210 implemented by GGNMOS. FIG. 2B is a schematic diagram of an ESD protection circuit 220 implemented by ground-gated NMOS with resistor (GRNMOS). FIG. 2C is a schematic diagram of an ESD protection circuit 230 implemented by an RC-Inverter NMOS.

Referring to FIG. 1 and FIG. 2A, the parasitic bipolar junction transistor (BJT) is formed in the NMOS M₁₁. A collector, emitter and base of a parasitic bipolar junction transistor (BJT) are inherently formed by the drain, source and substrate (or bulk) of the NMOS M₁₁. When an ESD event occurs at the first terminal 101, the large ESD voltage pulse will cause “Avalanche breakdown” at the interface of the N-type drain and P-type substrate of the NMOS M₁₁, letting large current to flow into the substrate of the NMOS M₁₁ and later be picked up by the bulk terminal (Ground). At this moment this current and the resistance will contribute an I-R drop to the parasitic BJT, which is inherently formed by the drain (as collector), substrate/bulk (as base) and source (as emitter). This BJT is then turned on and provides a very low-resistance path for this NMOS M₁₁ to release the ESD current instantly.

Referring to FIG. 2B, a ground-connected resistor R₂₁ is coupled to the gate of the NMOS M₂₁ of the ESD protection circuit 220. The resistor R₂₁ can be used to store electric charges, so that the NMOS M₂₁ can be “slightly” turned on when an ESD event occurs, and the ESD discharge current can be quickly directed to the ground. The ESD protection circuits shown in FIG. 2A and FIG. 2B are passive protection circuits, which are “passively” triggered by ESD events. For one having ordinary skill in the art, it is appreciated that the operations of the aforementioned passive protection circuits are well-known, and the details will be omitted here.

The ESD protection circuit 230 shown in FIG. 2C is an active-type protection circuit, which uses an extra detection mechanism to detect ESD events, thereby a faster response time can be achieved to direct the ESD discharge current to the ground. Specifically, the ESD protection circuit 230 may include a low-pass filter (e.g. resistor R₃₁ and capacitor C₃₁), an inverter (e.g. PMOS M₃₁ and NMOS M₃₂), and an ESD device (e.g. NMOS M₃₃). When an ESD event (e.g. a high frequency signal) occurs, the capacitor C₃₁ may become shorted due to the high frequency signal, so that the voltage at the node N31 will be drawn to the ground quickly. Meanwhile, the output terminal (node N32) of the inverter will be charged to a high logic level, so that the NMOS M₃₃ is turned on and the ESD discharge current is directed to the ground.

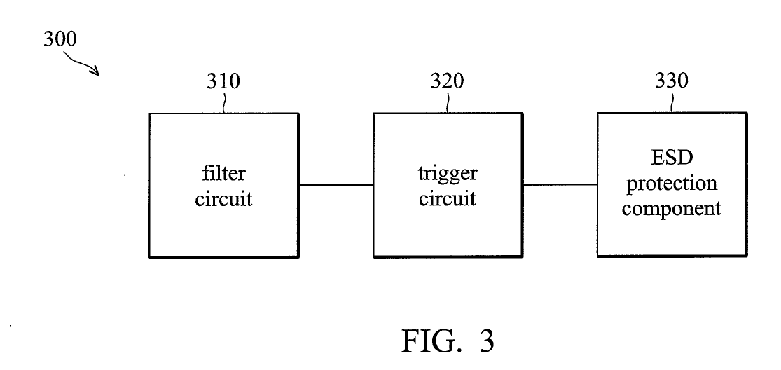

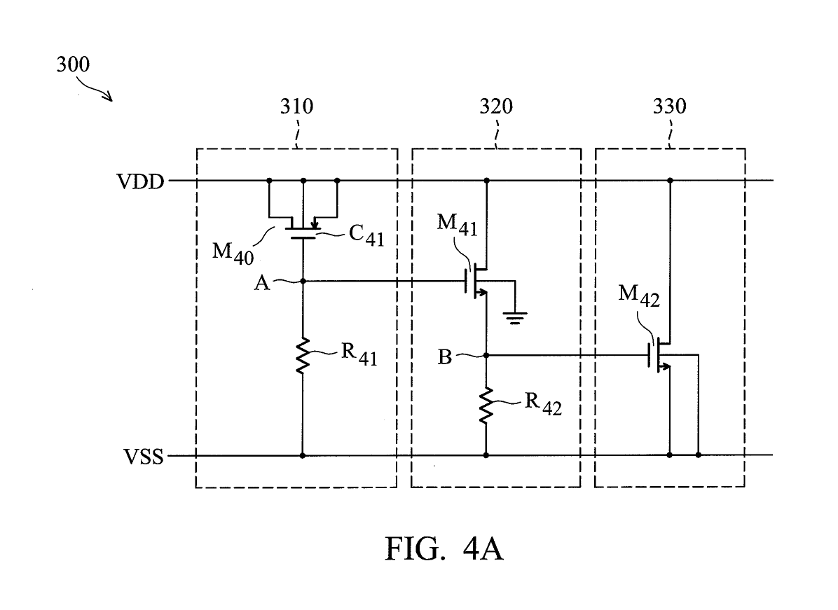

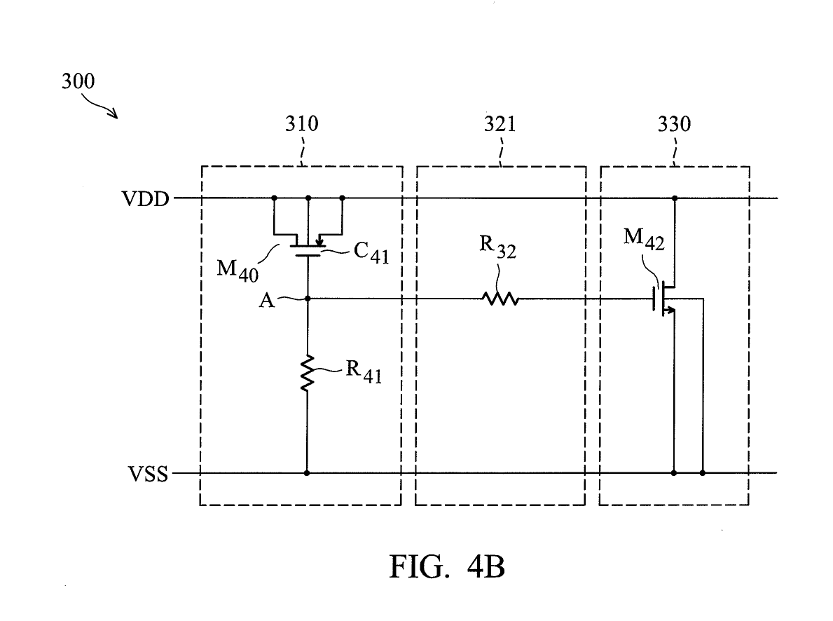

FIG. 3 is a schematic block diagram of the ESD protection circuit 300 in accordance with an embodiment of the invention. Referring to FIG. 1 and FIG. 3, the ESD protection circuit 300 is configured to replace the ESD protection circuit 102 shown in FIG. 1. In an embodiment, the ESD protection circuit 300 is coupled between a first power rail and a second power rail, and the ESD protection circuit 300 may include a filter circuit 310, a trigger circuit 320, and an ESD protection device 330. The first power rail may be coupled to the first terminal 101, and the second power rail may be coupled to the second terminal 106. The filter circuit 310 may be a high-pass filter (e.g. a first-order RC high-pass filter) as a signal detection stage. That is, the filter circuit 310 may detect whether the supply voltage (e.g. the voltage VDD at the first terminal 101 and/or the voltage VSS at the second terminal 106) of the ESD protection circuit 300 changes significantly. When the supply voltage (e.g. VDD and/or VSS) of the ESD protection circuit 300 changes significantly (e.g. an ESD event caused by positive electric charges occurs on the first power rail), the filter circuit 310 may drive the trigger circuit 320. The trigger circuit 320 is configured to provide a “weak” driving voltage to the ESD protection device 330. For example, the trigger circuit 320 may be an NMOS source follower. For example, when the supply voltage (e.g. VDD and/or VSS) of the ESD protection circuit 300 changes significantly (e.g. an ESD event caused by positive electric charges occurs on the first power rail), the ESD protection device 330 may direct the ESD current to the ground, thereby preventing damage to the internal circuit. In other embodiments, if an ESD event caused by negative electric charges occurs on the first power rail, the negative electric charges can be directed to the ground through the parasitic diode of the ESD protection device 330, thereby preventing damage to the internal circuit. In an embodiment, the trigger circuit 320 can be replaced by a buffer circuit 321 which will be described in the following embodiment of FIG. 4B.

FIG. 4A is a schematic diagram of the ESD protection circuit 300 in accordance with an embodiment of the invention. As illustrated in FIG. 4A, the filter circuit 310 may be a first-order RC high-pass filter, which includes a capacitor C₄₁ and a resistor R₄₁, wherein the capacitor C₄₁ can be implemented by a MOSFET, and the resistor R₄₁ may be implemented by a poly-silicon resistor, a well resistor, or a diffusion resistor. For example, the PMOS M₄₀ being a capacitor C₄₁ is turned off at general situations. When there is a transient to the voltage VDD, such as occurrence of an ESD event, the PMOS M₄₀ may be turned on. In an embodiment, the time constant, which is the product of the resistor R₄₁ and the capacitor C₄₁, of the filter circuit 310 may be 0.1 microsecond. It should be noted that the 0.1 microsecond is an example, and other numeric values can be used in other embodiments of the invention. In the embodiment of FIG. 4A, the trigger circuit 320 is implemented by a source follower. The source follower includes a NMOS M₄₁ and a resistor R₄₂. The drain of the NMOS M₄₁ is coupled to the voltage VDD, and the gate of the NMOS M₄₁ is coupled to the node A of the filter circuit 310, and the source of the NMOS M₄₁ is coupled to node B. The first terminal of the resistor R₄₂ is coupled to the node B, and the second terminal of the resistor R₄₂ is coupled to the voltage VSS. The gate of NMOS M₄₂ of the ESD protection device 330 is coupled to the node B for receiving a voltage V_{B} at the node B, thereby enabling the ESD protection device 330. The source and drain of the ESD protection device 330 are coupled to the voltages VSS and VDD, respectively. In an embodiment, a parasitic BJT is generated within the ESD protection device 330, and the drain of the ESD protection device 330 may be the collector of the parasitic BJT, and the source of the ESD protection device 330 may be the emitter of the parasitic BJT. The base of the parasitic BJT is coupled to the voltage VSS via the parasitic resistor of the substrate (or P-well).

FIG. 4B is a schematic diagram of the ESD protection circuit 300 in accordance with another embodiment of the invention. The buffer circuit 321 in FIG. 4B may be implemented by a resistor R₃₂. The resistor R₃₂ may be a poly-silicon resistor, a well resistor, a diffusion resistor, or an NMOS resistor. The first terminal of the resistor R₃₂ is coupled to the node A of the filter circuit 310, and the second terminal of the resistor R₃₂ is coupled to the gate of the NMOS M₄₂ of the ESD protection device 330. In other embodiments, the buffer circuit 321 may be implemented by one or more diodes, and the number of diodes may be determined based on need. In addition, the aforementioned diodes may be physical diodes or parasitic diodes. A physical diode may be a common diode having a simple structure, a Zener diode, or other type of diodes.

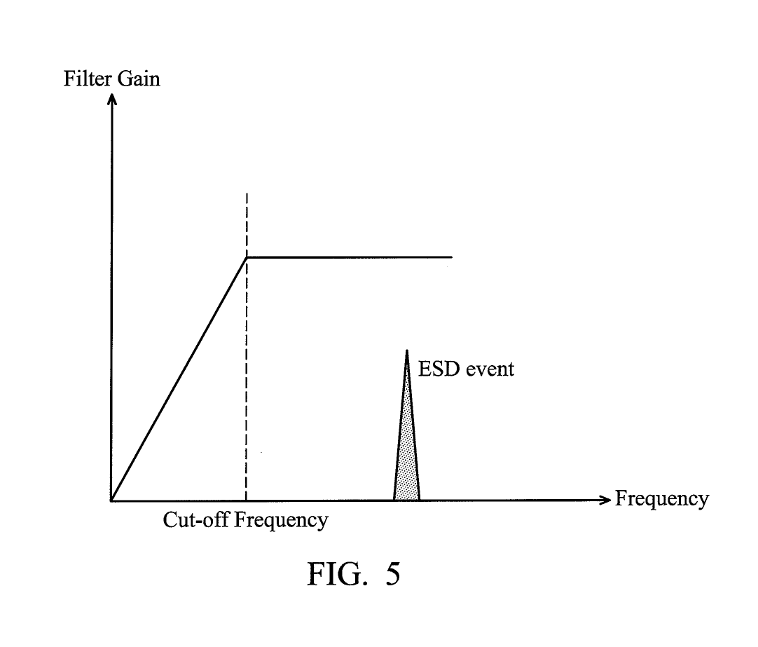

FIG. 5 is a diagram illustrating the filter gain of the filter circuit 310 in accordance with an embodiment of the invention. Since an ESD event indicates that a sudden and significant voltage change, the ESD event may be a high-frequency signal to the filter. Referring to FIG. 4A and FIG. 5, the filter circuit 310 may allow the ESD event (i.e. high frequency signal) to pass through. Specifically, when a transient happens to the voltage VDD (i.e. a high frequency signal is generated), since the filter circuit 310 is a high-pass filter, and the high frequency signal will not be filtered by the filter circuit 310. In addition, the voltage V_{A} (i.e. the voltage at the gate of PMOS M₄₀ or the gate of NMOS M₄₁) at the node A, which is generated by the current flowing through the resistor R₄₁, may enable the NMOS M₄₁ of the trigger circuit 320.

Referring to FIG. 4A, when the NMOS M₄₁ is turned on, a voltage V_{B} is generated at the node B by the current flowing through the NMOS M₄₁, thereby enabling the ESD protection device 330. In the embodiment, the resistance value (e.g. around 0.5K Ω) of the resistor R₄₂ (e.g. a poly-silicon resistor) is designed to make the NMOS M₄₂ of the ESD protection device 330 enter a soft turn-on status. The soft turn-on status may be regarded as the status at which the voltage V_{B} (the gate activation voltage of the NMOS M₄₂) at the node B is lower than the voltage V_{A} at the node A. When the NMOS M₄₂ is in a soft turn-on status, the NMOS M₄₂ is conducted, so that the ESD current can be directed to the ground via the NMOS M₄₂. In addition, since the NMOS M₄₂ is conducted, the ESD current can be quickly directed to the ground, thereby preventing damage to components of the internal circuit. Furthermore, since the NMOS M₄₂ is activated with or under a lower gate voltage (for example, under soft turn-on status), the reliability of the NMOS M₄₂ will not become attenuated quickly. For example, the resistor R₄₂ may be a well resistor, a diffusion resistor or an NMOS resistor in addition to a poly-silicon resistor. Referring to FIG. 4B again, when a transient happens to the voltage VDD (i.e. a high-frequency signal is generated), since the filter circuit 310 is a high-pass filter, the high-frequency signal will not be filtered by the filter circuit 310, and the voltage V_{A} at the node A, which is generated by the current flowing through the resistor R₄₁ in the filter circuit 310, is buffered by the resistor R₃₂ of the buffer circuit 321, and thus the NMOS M₄₂ will not be activated quickly, so that the reliability of the NMOS M₄₂ will not become attenuated quickly.

In an embodiment, the NMOS M₄₁ of the ESD protection circuit 300 can be designed having the smallest width/length ratio (W/L) of an NMOS. If the 18 nm technology is used, the width/length ratio of the NMOS M₄₁ can be expressed as: (W/L)_{n,min}=(10/0.25), and the area of the resistor R₄₂ may be 4.6 μm². Referring to FIG. 2C again, the smallest width/length ratio of the PMOS M₃₁ of the inverter in the ESD protection circuit 230 can be expressed as: (W/L)_{p,min}=(40/0.25), and the size of the PMOS M₃₁ is much larger than that of the resistor R₄₂ of the ESD protection circuit 300. Accordingly, the area of the ESD protection circuit 300 of the embodiment of the invention is smaller than that of the ESD protection circuit 230.

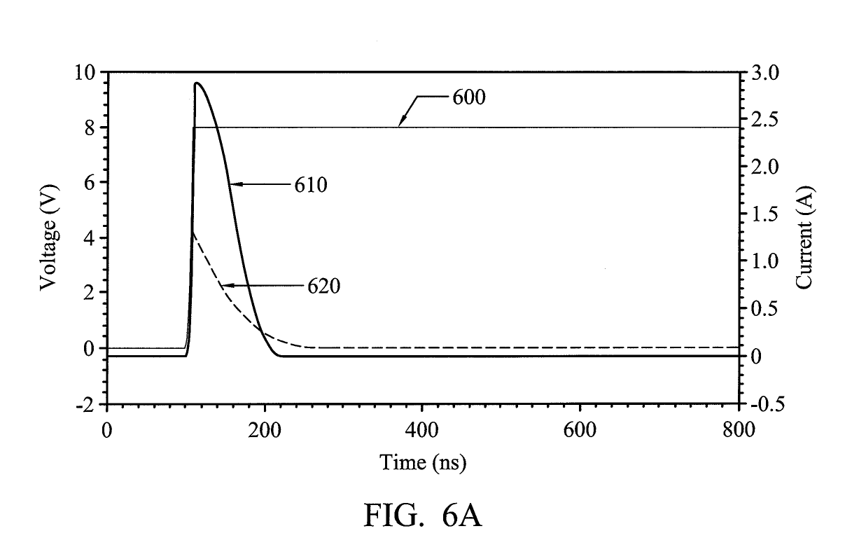

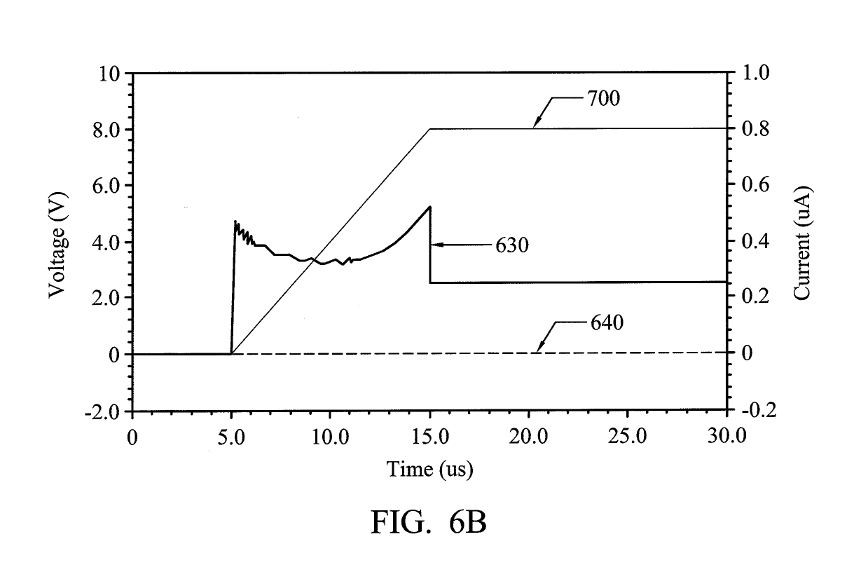

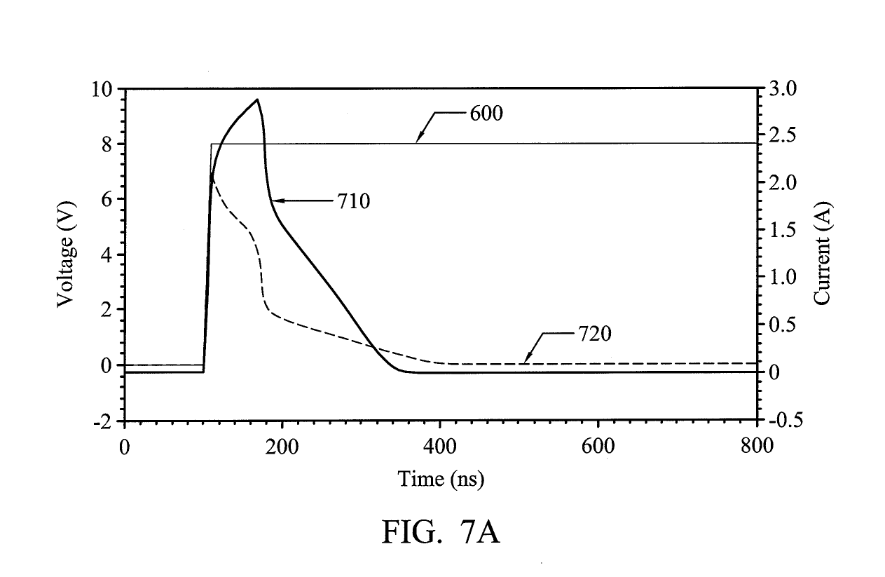

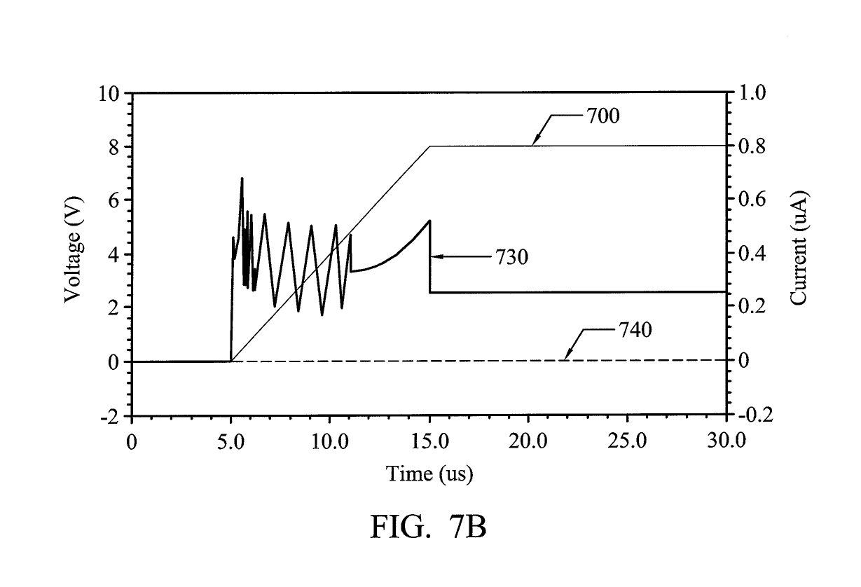

FIGS. 6A-6B are diagrams illustrating the frequency response of the ESD protection circuit 300 in accordance with an embodiment of the invention. FIGS. 7A-7B are diagrams illustrating the frequency response of the ESD protection circuit 230 shown in FIG. 2C. The frequency gain of the ESD protection circuits 300 and 230 can be obtained by using the simulation tool such as Cadence Spectre Circuit Simulator. For example, the resistor R₃₁ in FIG. 2C may be 100 KΩ and the capacitor C₃₁ may be 1 pF. The resistor R₄₁ in FIG. 4A may be 100KΩ and the capacitor C₄₁ may be 1 pF. In the embodiment, different transient waveforms are used to test the frequency response of the ESD protection circuits 300 and 230. For example, referring to FIG. 6A and FIG. 7A, an ESD event is simulated by the transient waveform 600 indicating the rising of voltage difference VDD-VSS from 0V to 8V within 10 ns. When receiving the waveform 600, the ESD protection circuits may direct the ESD current to the ground. The peak value of the ESD current flowing through the NMOS M₄₂ of the ESD protection circuit 300 (i.e. waveform 610 in FIG. 6A) is the same as that of the ESD current flowing through the NMOS M₃₃ (i.e. waveform 710 in FIG. 7A). However, the peak input voltage of the NMOS M₄₂ of the ESD device 330 (i.e. waveform 620 in FIG. 6A) can be significantly reduced when compared with the gate voltage of the NMOS M₃₃ of the ESD protection circuit 230 (i.e. waveform 720 in FIG. 7A). That is, the gate voltage of the NMOS M₄₂ can be decreased, thereby reducing the possibility that the NMOS M₄₂ is damaged by an ESD event.

Referring to FIG. 6B and FIG. 7B, in another embodiment, a common power activation sequence is simulated by a waveform 700 indicating the rising of the voltage difference VDD-VSS from 0V to 8V within 10 μs. However, the rising speed of the voltage in the transient waveform 700 is slow, and that is, the frequency of the transient waveform 700 is much lower than the cut-off frequency of the high-pass filter in the first stage. Accordingly, the capacitor C₄₁ in the ESD protection circuit 300 can be regarded as being “open-circuited” (not conducted), and the gate of the NMOS M₄₁ can be regarded as being grounded. Therefore, the NMOS M₄₁ of the ESD protection circuit 300 will not be turned on, so that the NMOS M₄₂ will not be conducted (i.e. the details can be referred to in FIG. 6B, especially the current waveform 630 flowing into the drain of the NMOS M₄₂ and the voltage waveform 640 at the gate of the NMOS M₄₂. This indicates that the ESD component 330 will not be activated during a common power activation sequence). In an embodiment, the cut-off frequency of the high-pass filter is (2πR₄₁C₄₁)⁻¹, and the time constant of the product of R₄₁ and C₄₁ may be 0.1 μs. For example, the timing constant can be obtained by using a resistor R₄₁ having a resistance of 100KΩ and a capacitor C₄₁ having a capacitance value of 1 pF. In addition, appropriate resistance value and capacitance value can be selected to implement the high-pass filter according to user's need. In other embodiments, the user may also design other filters having a different cut-off frequency according to need. Compared with FIG. 7B, the same ESD protection ability as the ESD protection circuit 230 can be achieved by the ESD protection circuit 300 with a smaller area (i.e. the details can be referred to the current waveform 730 flowing into the drain of the NMOS M₃₃ and the voltage waveform of the gate voltage of the NMOS M₃₃ in FIG. 7B). In the embodiment, there are a little leakage currents in the NMOS M₄₂ and the NMOS M₃₃ in respective ESD protection circuits 300 and 230, wherein the leakage currents are within a tolerable range.

In view of the above, an active-type ESD protection circuit is provided in the embodiments of the invention. The ESD protection circuit may detect an ESD event on an IC by a signal detection stage (e.g. filter circuit 310), and enable a driving circuit (e.g. trigger circuit 320 in FIG. 4A, or the buffer circuit 321 in FIG. 4B) to direct the ESD current generated by the ESD event to the ground via an ESD protection device (e.g. ESD protection device 330), thereby preventing damage to the internal circuit of the IC.

While the invention has been described by way of example and in terms of the embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge (ESD) protection circuit, comprising:
a filter circuit, comprising:
a capacitor, wherein a first terminal of the capacitor is coupled to a first rail having a first voltage, and a second terminal of the capacitor is coupled to a first node; and
a first resistor, wherein a first terminal of the first resistor is coupled to the first node, and a second terminal of the first resistor is coupled to a second rail having a second voltage, wherein the first voltage is higher than the second voltage;
an ESD protection device, comprising:
a first NMOS having a gate, a drain, and a source, wherein the drain is coupled to the first rail, and the source is coupled to the second rail, and the gate receives a third voltage to activate the first NMOS; and
a trigger circuit, coupled between the filter circuit and the ESD protection device.

2. The ESD protection circuit as claimed in claim 1, wherein the trigger circuit is a source follower, and the source follower comprises:
a second NMOS having a gate, a drain and a source, wherein the gate is coupled to the first node, and the drain is coupled to the first rail, and the source is coupled to a second node; and
a second resistor, wherein a first terminal of the second resistor is coupled to the second node, and a second terminal of the second resistor is coupled to the second rail.

3. The ESD protection circuit as claimed in claim 2, wherein the gate of the ESD protection device is coupled to the second node.

4. The ESD protection circuit as claimed in claim 1, wherein the first resistor is a poly-silicon resistor, a well resistor, a diffusion resistor, or an NMOS resistor.

5. The ESD protection circuit as claimed in claim 2, wherein the second resistor is a poly-silicon resistor, a well resistor, a diffusion resistor, or an NMOS resistor.

6. The ESD protection circuit as claimed in claim 1, wherein an ESD event caused by positive electric charges occurs on the first rail, the trigger circuit provides the third voltage to the first NMOS, so that the first NMOS is in a soft turn-on status, and the positive electric charges are directed to the second rail through the first NMOS.

7. The ESD protection circuit as claimed in claim 6, wherein when the ESD event occurs on the first rail, the first node has a fourth voltage, wherein the third voltage is lower than the fourth voltage.

8. The ESD protection circuit as claimed in claim 1, wherein the capacitor is implemented by a third NMOS, and a source, drain, and base of the third NMOS are coupled to the first rail.

9. The ESD protection circuit as claimed in claim 2, wherein the first NMOS and the second NMOS are implemented by using a smallest width/length ratio.

10. The ESD protection circuit as claimed in claim 1, wherein the filter circuit is a high-pass filter circuit.

11. The ESD protection circuit as claimed in claim 1, wherein the first rail is coupled to an input/output terminal.

12. An electrostatic discharge (ESD) protection circuit, comprising:
a filter circuit, comprising:
a capacitor, wherein a first terminal of the capacitor is coupled to a first rail having a first voltage, and a second terminal of the capacitor is coupled to a first node; and
a first resistor, wherein a first terminal of the first resistor is coupled to the first node, and a second terminal of the first resistor is coupled to a second rail having a second voltage, wherein the first voltage is higher than the second voltage;
an ESD protection device, comprising:
a first NMOS having a gate, a drain, and a source, wherein the drain is coupled to the first rail, and the source is coupled to the second rail, and the gate receives a third voltage to activate the first NMOS; and
a buffer circuit, coupled between the filter circuit and the ESD protection device, wherein the buffer circuit is implemented by a first resistor or a diode.

13. The ESD protection circuit as claimed in claim 12, wherein the first resistor is a poly-silicon resistor, a well resistor, a diffusion resistor, or an NMOS resistor.

14. A semiconductor device, comprising:
a high-pass filter circuit, configured to provide a first voltage;
an electrostatic discharge (ESD) protection device; and
a trigger circuit, coupled to the high-pass filter circuit and the ESD protection device, wherein when an ESD event caused by positive electric charges occurs on a first rail, the trigger circuit provides a second voltage, which is lower than the first voltage, to the ESD protection device, so that electric charges of the ESD event are directed to a second rail through the ESD protection device.

15. The semiconductor device as claimed in claim 14, wherein the high-pass filter circuit comprises:
a capacitor, wherein a first terminal of the capacitor is coupled to the first rail, and a second terminal of the capacitor is coupled to a first node; and
a first resistor, wherein a first terminal of the first resistor is coupled to the first node, and a second terminal of the first resistor is coupled to the second rail;
wherein the trigger circuit comprises:
a first NMOS, having a gate, a drain, and a source, wherein the gate is coupled to the high-pass filter circuit, and the drain is coupled to the first rail, and the source is coupled to a second node; and
a second resistor, wherein a first terminal of the second resistor is coupled to the second node, and a second terminal of the second resistor is coupled to the second rail;
wherein the ESD protection device comprises:
a second NMOS, having a gate, a drain, and a source, wherein the gate is coupled to the second node, and the drain is coupled to the first rail, and the source is coupled to the second rail.

16. The semiconductor device as claimed in claim 14, wherein the first rail is coupled to an input/output terminal or a power supply terminal, and the second rail is coupled to a low-level power supply terminal.

17. The semiconductor device as claimed in claim 16, wherein the first NMOS and the second NMOS are implemented by using a smallest width/length ratio.

18. The semiconductor device as claimed in claim 14, wherein when the ESD event occurs on the first rail, the trigger circuit provides the second voltage to a first NMOS, so that the first NMOS is in a soft turn-on status, and the electric charges of the ESD event are directed to the second rail via the first NMOS.
